(19) United States
(12) Patent Application Publication
(10) Pub. No.: US 2026/0159378 A1
(43) Pub. Date: Jun. 11, 2026

(54) Sensor Module And Vehicle

(71) Applicant: SEIKO EPSON CORPORATION, Tokyo (JP)

(72) Inventor: Toru WATANABE, Matsumoto (JP)

(21) Appl. No.: 19/367,888

(22) Filed: Oct. 24, 2025

(30) Foreign Application Priority Data
Oct. 25, 2024 (JP) 2024-188135

(51) Int. Cl. B81B 7/00

(52) U.S. Cl. CPC B81B 7/0077; B81B 2201/0235; B81B 2201/0242; B81B 2207/012; B81B 2207/07; B81B 2207/096

(57) ABSTRACT

A sensor module includes a package having a first space and a second space overlapping when viewed from a first direction, a vibrator element and an integrated circuit disposed in the first space, and a MEMS sensor disposed in the second space, wherein the integrated circuit is electrically coupled to the vibrator element and the MEMS sensor, and the vibrator element, the integrated circuit, and the MEMS sensor overlap one another when viewed from the first direction.

The present application is based on, and claims priority from JP Application Serial Number 2024-188135, filed Oct. 25, 2024, the disclosure of which is hereby incorporated by reference herein in its entirety.

### BACKGROUND

### 1. Technical Field

The present disclosure relates to a sensor module and a vehicle.

### 2. Related Art

A sensor module including a gyro sensor and an acceleration sensor is known.

For example, JP-A-2023-50622 describes an inertial sensor module including a first sensor having a first axis, a second axis, and a third axis as detection axes, and a second sensor having higher accuracy than the first sensor and having the third axis as a detection axis. The first sensor and the second sensor are disposed on one plane in a package and are hermetically sealed by the package.

JP-A-2023-50622 is an example of the related art.

In the inertial sensor module described in JP-A-2023-50622, since the first sensor and the second sensor are disposed on the same plane in one internal space of the package, the occupied area may increase.

### SUMMARY

An aspect of a sensor module according to the present disclosure includes a package having a first space and a second space overlapping when viewed from a first direction, a vibrator element and an integrated circuit disposed in the first space, and a MEMS sensor disposed in the second space, wherein the integrated circuit is electrically coupled to the vibrator element and the MEMS sensor, and the vibrator element, the integrated circuit, and the MEMS sensor overlap one another when viewed from the first direction.

An aspect of a vehicle according to the present disclosure includes the sensor module.

### BRIEF DESCRIPTION OF THE DRAWINGS

FIG. 1 is a plan view schematically showing a sensor module according to an embodiment.

FIG. 2 is a cross-sectional view schematically showing the sensor module according to the present embodiment.

FIG. 3 is a cross-sectional view schematically showing the sensor module according to the present embodiment.

FIG. 4 is a side view schematically showing a substrate of the sensor module according to the present embodiment.

FIG. 5 is a plan view schematically showing a MEMS sensor of the sensor module according to the present embodiment.

FIG. 6 is a cross-sectional view schematically showing the MEMS sensor of the sensor module according to the present embodiment.

FIG. 7 is a cross-sectional view schematically showing a three-axis angular velocity sensor of the sensor module according to the present embodiment.

FIG. 8 is a cross-sectional view schematically showing the three-axis acceleration sensor of the sensor module according to the present embodiment.

FIG. 9 is a plan view schematically showing a vibrator element of the sensor module according to the present embodiment.

FIG. 10 shows an operation of the vibrator element of the sensor module according to the present embodiment.

FIG. 11 shows the operation of the vibrator element of the sensor module according to the present embodiment.

FIG. 12 is a block diagram showing an integrated circuit of the sensor module according to the present embodiment.

FIG. 13 is a plan view schematically showing a vehicle according to the embodiment.

### DESCRIPTION OF EMBODIMENTS

Hereinafter, preferred embodiments of the present disclosure will be described in detail with reference to the drawings. Note that the embodiments to be described below do not unduly limit the present disclosure described in What is claimed is. In addition, not all configurations to be described below are necessarily essential component elements of the present disclosure.

### 1. Sensor Module

### 1.1. Overall Configuration

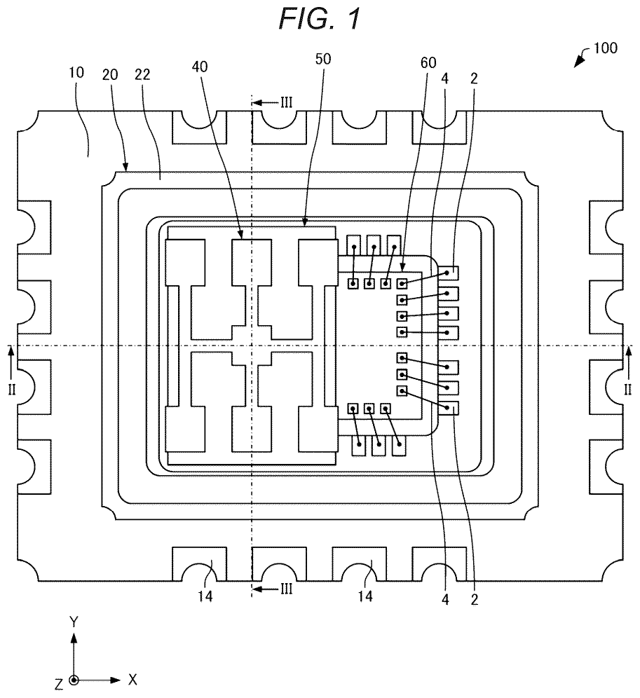

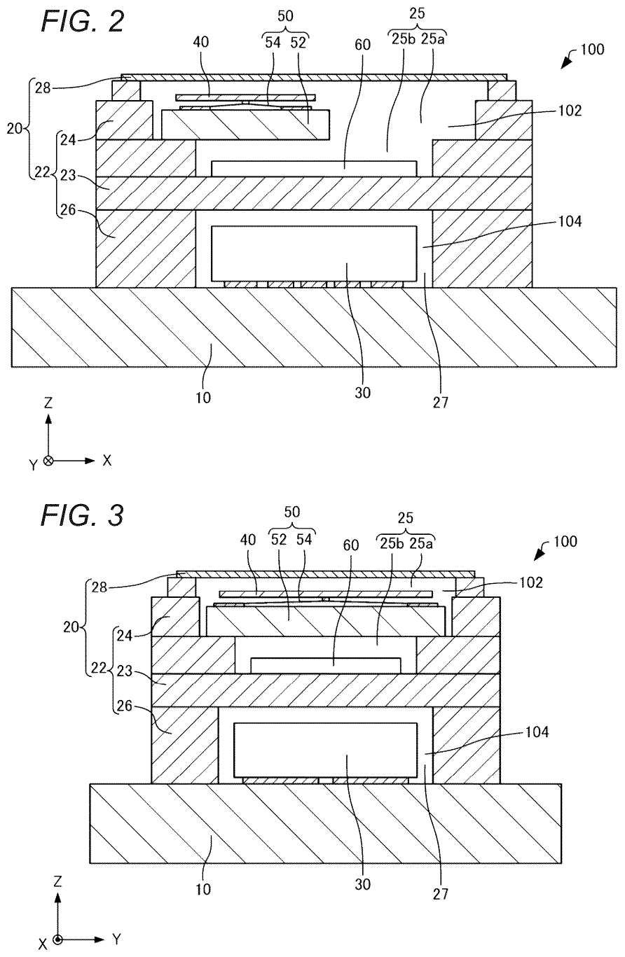

First, a sensor module according to the embodiment will be described with reference to the drawings. FIG. 1 is a plan view schematically showing a sensor module 100 according to the present embodiment. FIG. 2 is a cross-sectional view taken along line II-II in FIG. 1 schematically showing the sensor module 100 according to the present embodiment. FIG. 3 is a cross-sectional view taken along line III-III in FIG. 1 schematically showing the sensor module 100 according to the present embodiment. Note that FIGS. 1 to 3 show an X axis, a Y axis, and a Z axis as three axes orthogonal to one another.

As shown in FIGS. 1 to 3, the sensor module 100 includes, for example, a substrate 10, a package 20, a micro electro mechanical systems (MEMS) sensor 30, a vibrator element 40, a support substrate 50, and an integrated circuit 60. For convenience, illustration of a lid 28 of the package 20 is omitted in FIG. 1.

The substrate 10 supports the package 20 and the MEMS sensor 30. The substrate 10 may be mounted on a mounting substrate (not shown). The substrate 10 has a thickness direction in a first direction. In the illustrated example, the first direction is a Z-axis direction. Hereinafter, the arrow side in the Z-axis direction is also referred to as “upper”, and the opposite side is also referred to as “lower”.

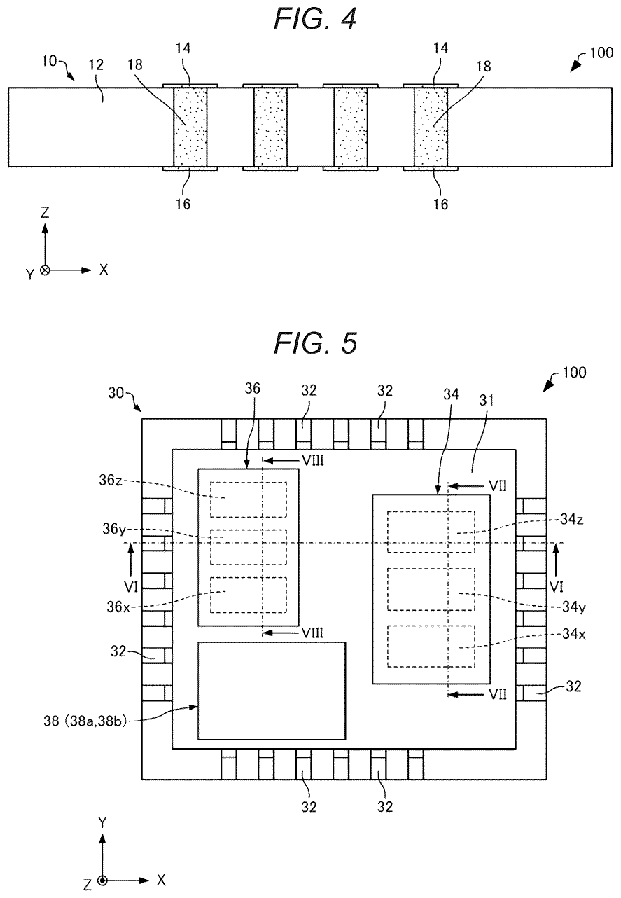

FIG. 4 is a side view schematically illustrating the substrate 10. As shown in FIG. 4, the substrate 10 includes, for example, a base portion 12, a first terminal 14, a second terminal 16, and a conductive portion 18. The first terminal 14 is provided on one surface of the base portion 12. The second terminal 16 is provided on the other surface of the base portion 12. The second terminal 16 is provided on a side of the base portion 12 opposite to the MEMS sensor 30. In the illustrated example, the first terminal 14 is provided on the upper surface of the base portion 12, and the second terminal 16 is provided on the lower surface of the base portion 12. For example, a plurality of the first terminals 14 are provided. For example, a plurality of the second terminals 16 are provided. The first terminal 14 and the second terminal 16 are electrically coupled by the conductive portion 18 provided on a side surface of the base portion 12. When the substrate 10 is mounted on a mounting substrate (not shown), the second terminal 16 is electrically coupled to the mounting substrate. The materials of the terminals 14 and 16 and the conductive portion 18 are, for example, metals such as copper or gold.

The substrate 10 is, for example, softer than the package 20. Specifically, the base portion 12 of the substrate 10 is formed using a material softer than a base 22 of the package 20. The substrate 10 may be a flexible substrate. The substrate 10 is not particularly limited, and may be a ceramic substrate or the like. The substrate 10 may include a lead frame.

The package 20 is provided on the substrate 10. In the example shown in FIG. 1, the package 20 has a shape in which the length in the X-axis directions is larger than the length in Y-axis directions. As shown in FIGS. 2 and 3, the package 20 includes the base 22 and the lid 28.

The material of the base 22 is, for example, ceramic such as aluminum oxide. The base 22 includes, for example, a flat plate portion 23, a first wall portion 24, and a second wall portion 26. In the illustrated example, the base 22 has a substantially H-shape.

The flat plate portion 23 is provided between the substrate 10 and the lid 28. The flat plate portion 23 is provided between the first wall portion 24 and the second wall portion 26. The flat plate portion 23 has a planar shape. In the illustrated example, the shape of the flat plate portion 23 is a rectangular parallelepiped shape.

The first wall portion 24 is provided on the upper surface of the flat plate portion 23. The first wall portion 24 stands upward from the flat plate portion 23. A first recess 25 is formed in the base 22. The first wall portion 24 and the flat plate portion 23 define the first recess 25. The flat plate portion 23 defines the bottom surface of the first recess 25. In the illustrated example, the base 22 has the first recess 25 opened upward by the first wall portion 24 and the flat plate portion 23. The first recess 25 has, for example, a first portion 25a and a second portion 25b overlapping each other when viewed from the Z-axis direction (hereinafter, also referred to as “in plan view”). The first portion 25a is located between the lid 28 and the second portion 25b. In plan view, the area of the first portion 25a is larger than the area of the second portion 25b. The second portion 25b is provided below the first portion 25a. Due to the first portion 25a and the second portion 25b, the base 22 has the stepped first recess 25.

The second wall portion 26 is provided on the lower surface of the flat plate portion 23. The second wall portion 26 stands downward from the flat plate portion 23. A second recess 27 is formed in the base 22. The second wall portion 26 and the flat plate portion 23 define the second recess 27. The flat plate portion 23 defines the bottom surface of the second recess 27. In the illustrated example, the base 22 has the second recess 27 opened downward by the second wall portion 26 and the flat plate portion 23. The second recess 27 is opened on the side opposite to the first recess 25.

The lid 28 is coupled to the base 22. The first wall portion 24 may include a seal ring, and the lid 28 may be coupled to the seal ring of the first wall portion 24. The lid 28 may be welded to the base 22. When the material of the base 22 is ceramic, the material of the lid 28 is preferably an alloy such as Kovar. Accordingly, the difference in linear expansion coefficient between the lid 28 and the base 22 can be reduced.

The lid 28 closes the first recess 25. Specifically, the lid 28 closes the opening of the first recess 25. The first recess 25 forms a first space 102. The package 20 has the first space 102. The first space 102 is hermetically sealed. The first space 102 is, for example, in a depressurized state, preferably in a state close to vacuum. Accordingly, the viscous resistance of the first space 102 can be reduced, and the vibration characteristics of the vibrator element 40 disposed in the first space 102 can be improved. The atmosphere of the first space 102 is not particularly limited.

The substrate 10 closes the second recess 27. Specifically, the substrate 10 closes the opening of the second recess 27. The second recess 27 defines a second space 104. The package 20 has the second space 104. The first space 102 and the second space 104 overlap each other in plan view. The second space 104 may be hermetically sealed or not. However, in consideration of reduction of moisture entering the MEMS sensor 30 disposed in the second space 104, the second space 104 is preferably hermetically sealed.

### 1.2. MEMS Sensor

As shown in FIGS. 2 and 3, the MEMS sensor 30 is disposed in the second space 104. The MEMS sensor 30 is disposed on the substrate 10 in the second space 104. The MEMS sensor 30 is, for example, face-down mounted on the substrate 10 with the terminal surface facing downward. Accordingly, the MEMS sensor 30 can be directly coupled to a terminal (not illustrated) provided on the substrate 10, and thus, the sensor module 100 can be downsized. Although not illustrated, the MEMS sensor 30 may be mounted on the flat plate portion 23 of the base 22 instead of the substrate 10 as long as the MEMS sensor 30 is disposed in the second space 104.

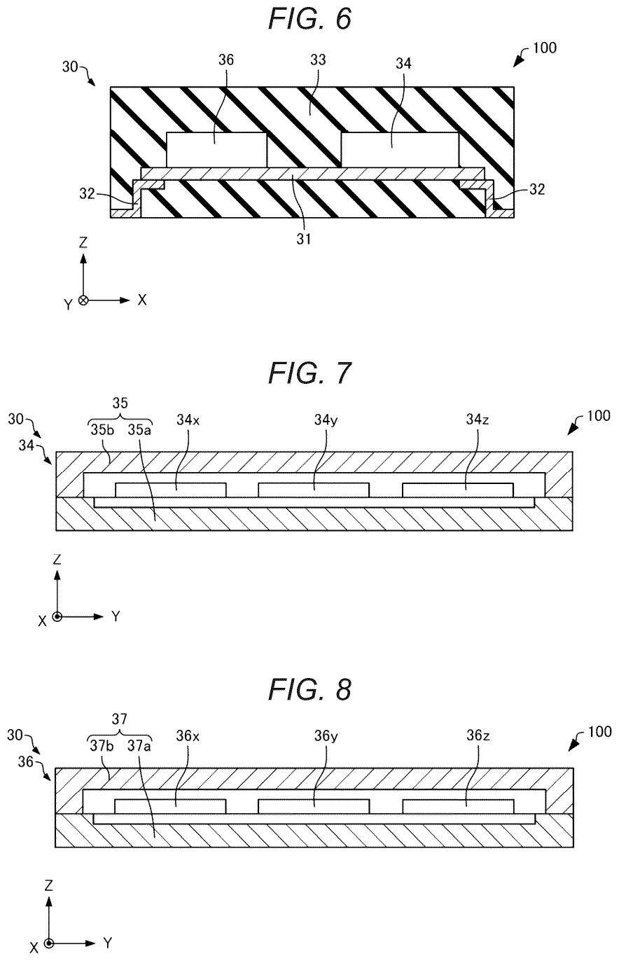

FIG. 5 is a plan view schematically showing the MEMS sensor 30. FIG. 6 is a cross-sectional view taken along line VI-VI in FIG. 5 schematically illustrating the MEMS sensor 30. The MEMS sensor 30 is, for example, a composite sensor that detects three-axis angular velocities and three-axis accelerations, and is a so-called 6DoF sensor.

As shown in FIGS. 5 and 6, the MEMS sensor 30 includes, for example, a substrate 31, a mold member 33, a three-axis angular velocity sensor 34, a three-axis acceleration sensor 36, and a circuit element 38. For convenience, the mold member 33 is omitted in FIG. 5.

The substrate 31 supports the three-axis angular velocity sensor 34, the three-axis acceleration sensor 36, and the circuit element 38. The substrate 31 includes a lead 32. For example, a plurality of the leads 32 are provided. In the example shown in FIG. 1, a plurality of pads 2 are provided on the base 22. The pad 2 is electrically coupled to the integrated circuit 60 via a wire bonding 4. The circuit element 38 of the MEMS sensor 30 is electrically coupled to the integrated circuit 60 via the lead 32, the pad 2, and the wire bonding 4.

As shown in FIG. 6, the mold member 33 is provided on the substrate 31. The molded member 33 covers the three-axis angular velocity sensor 34, the three-axis acceleration sensor 36, and the circuit element 38. The MEMS sensor 30 has a mold structure in which the three-axis angular velocity sensor 34, the three-axis acceleration sensor 36, and the circuit element 38 are mold sealed by the mold member 33. Although not illustrated, the MEMS sensor 30 may have a package structure housed in a ceramic package or the like instead of the mold structure.

FIG. 7 is a cross-sectional view taken along line VII-VII in FIG. 5 schematically illustrating the three-axis angular velocity sensor 34. The three-axis angular velocity sensor 34 can detect an angular velocity ωx around the X axis, an angular velocity ωy around the Y axis, and an angular velocity ωz around the Z axis. As shown in FIG. 7, the three-axis angular velocity sensor 34 includes an X-axis angular velocity sensor element 34x, a Y-axis angular velocity sensor element 34y, a Z-axis angular velocity sensor element 34z, and a package 35.

The package 35 houses the X-axis angular velocity sensor element 34x, the Y-axis angular velocity sensor element 34y, and the Z-axis angular velocity sensor element 34z. The package 35 includes a base 35a and a lid 35b that closes a recess formed in the base 35a.

The X-axis angular velocity sensor element 34x, the Y-axis angular velocity sensor element 34y, and the Z-axis angular velocity sensor element 34z are formed of MEMS. The three-axis angular velocity sensor 34 is formed in, for example, a step of forming the base 35a from one silicon layer (handle layer) of an SOI (silicon on insulator) substrate, a step of forming the angular velocity sensor elements 34x, 34y, and 34z from the other silicon layer (device layer), and a step of bonding the lid 35b formed of a silicon substrate to the base 35a. Accordingly, the three-axis angular velocity sensor 34 can be manufactured by a silicon semiconductor process.

The X-axis angular velocity sensor element 34x includes a fixed inter digital transducer fixed to the base 35a, a movable inter digital transducer disposed so as to mesh with the fixed inter digital transducer and displaceable in the Y-axis directions and the Z-axis directions with respect to the base 35a, and a drive inter digital transducer for vibrating the movable inter digital transducer in the Y-axis directions. When the angular velocity ωx around the X axis is applied to the X-axis angular velocity sensor element 34x in a state (drive vibration state) in which the movable inter digital transducer is vibrated in the Y-axis directions by energizing the drive inter digital transducer, a detection vibration in the Z-axis directions is excited in the movable inter digital transducer by the Coriolis force. The electrostatic capacitance between the fixed inter digital transducer and the movable inter digital transducer changes according to the detection vibration. Therefore, the change in the electrostatic capacitance can be extracted as an output signal, and the angular velocity ωx can be detected based on the extracted output signal. However, the configuration of the X-axis angular velocity sensor element 34x is not particularly limited as long as the angular velocity ωx can be detected.

The Y-axis angular velocity sensor element 34y includes a fixed inter digital transducer fixed to the base 35a, a movable inter digital transducer disposed so as to mesh with the fixed inter digital transducer and displaceable in the X-axis directions and the Z-axis directions with respect to the base 35a, and a drive inter digital transducer for vibrating the movable inter digital transducer in the X-axis directions. When the angular velocity ωy around the Y-axis is applied to the Y-axis angular velocity sensor element 34y in a state (drive vibration state) in which the movable inter digital transducer is vibrated in the X-axis directions by energizing the drive inter digital transducer, a detection vibration in the Z-axis directions is excited in the movable inter digital transducer by the Coriolis force. The electrostatic capacitance between the fixed inter digital transducer and the movable inter digital transducer changes according to the detection vibration. Therefore, the change in the electrostatic capacitance is extracted as an output signal, and the angular velocity ωy can be detected based on the extracted output signal. However, the configuration of the Y-axis angular velocity sensor element 34y is not particularly limited as long as the angular velocity ωy can be detected.

The Z-axis angular velocity sensor element 34z includes a fixed inter digital transducer fixed to the base 35a, a movable inter digital transducer disposed so as to mesh with the fixed inter digital transducer and displaceable in the X-axis directions and the Y-axis directions with respect to the base 35a, and a drive inter digital transducer for vibrating the movable inter digital transducer in the X-axis directions. When the angular velocity ωz around the Z axis is applied to the Z-axis angular velocity sensor element 34z in a state (drive vibration state) in which the movable inter digital transducer is vibrated in the X-axis directions by energizing the drive inter digital transducer, a detection vibration in the Y-axis directions is excited in the movable inter digital transducer by the Coriolis force. The electrostatic capacitance between the fixed inter digital transducer and the movable inter digital transducer changes according to the detection vibration. Therefore, the change in the electrostatic capacitance can be extracted as an output signal, and the angular velocity ωz can be detected based on the extracted output signal. However, the configuration of the Z-axis angular velocity sensor element 34z is not particularly limited as long as the angular velocity ωz can be detected.

The configuration of the three-axis angular velocity sensor 34 is not particularly limited. For example, the base 35a and the lid 35b may be formed of a material other than silicon such as glass. In the illustrated configuration, the angular velocity sensor elements 34x, 34y, and 34z are arranged along the Y-axis directions, but the arrangement thereof is not particularly limited. A package 320 may be segmented for each of the angular velocity sensor elements 34x, 34y, and 34z. In this case, the angular velocity sensor elements 34x, 34y, and 34z may be disposed to overlap one another in the Z-axis directions. Two or more angular velocity sensor elements selected from the angular velocity sensor elements 34x, 34y, and 34z may be integrally formed as one angular velocity sensor element. In other words, two or more of the angular velocities ωx, ωy, and ωz may be detected by one angular velocity sensor element. The angular velocity sensor is not limited to the three-axis angular velocity sensor 34 and the number of angular velocity detection axes may be two or one.

FIG. 8 is a cross-sectional view taken along line VIII-VIII in FIG. 5 schematically illustrating the three-axis acceleration sensor 36. The three-axis acceleration sensor 36 can detect an acceleration Ax in the X-axis directions, an acceleration Ay in the Y-axis directions, and an acceleration Az in the Z-axis directions. As shown in FIG. 8, the three-axis acceleration sensor 36 includes an X-axis acceleration sensor element 36x, a Y-axis acceleration sensor element 36y, a Z-axis acceleration sensor element 36z, and a package 37.

The package 37 houses the X-axis acceleration sensor element 36x, the Y-axis acceleration sensor element 36y, and the Z-axis acceleration sensor element 36z. The package 37 includes a base 37a and a lid 37b that closes a recess formed in the base 37a. Similar to the angular velocity sensor elements 34x, 34y, and 34z described above, the acceleration sensor elements 36x, 36y, and 36z are formed of MEMS, and the three-axis acceleration sensor 36 can be manufactured by a silicon semiconductor process.

The X-axis acceleration sensor element 36x includes a fixed inter digital transducer fixed to the base 37a and a movable inter digital transducer disposed so as to mesh with the fixed inter digital transducer and displaceable in the X-axis directions with respect to the base 37a. When the acceleration Ax in the X-axis directions is applied to the X-axis acceleration sensor element 36x, the movable inter digital transducer is displaced in the X-axis directions. The electrostatic capacitance between the fixed inter digital transducer and the movable inter digital transducer changes according to the displacement. Therefore, the change in the electrostatic capacitance is extracted as an output signal, and the acceleration Ax can be detected based on the extracted output signal. However, the configuration of the X-axis acceleration sensor element 36x is not particularly limited as long as the acceleration Ax can be detected.

The Y-axis acceleration sensor element 36y includes a fixed inter digital transducer fixed to the base 37a and a movable inter digital transducer disposed so as to mesh with the fixed inter digital transducer and displaceable in the Y-axis directions with respect to the base 37a. When the acceleration Ay in the Y-axis directions is applied to the Y-axis acceleration sensor element 36y, the movable inter digital transducer is displaced in the Y-axis directions. The electrostatic capacitance between the fixed inter digital transducer and the movable inter digital transducer changes according to the displacement. Therefore, the change in the electrostatic capacitance is extracted as an output signal, and the acceleration Ay can be detected based on the extracted output signal. However, the configuration of the Y-axis acceleration sensor element 36y is not particularly limited as long as the acceleration Ay can be detected.

The Z-axis acceleration sensor element 36z includes a fixed inter digital transducer fixed to the base 37a and a movable inter digital transducer disposed so as to mesh with the fixed inter digital transducer and displaceable in the Z-axis directions with respect to the base 37a. When the acceleration Az in the Z-axis direction is applied to the Z-axis acceleration sensor element 36z, the movable inter digital transducer is displaced in the Z-axis directions. The electrostatic capacitance between the fixed inter digital transducer and the movable inter digital transducer changes according to the displacement. Therefore, the change in the electrostatic capacitance can be extracted as an output signal, and the acceleration Az can be detected based on the extracted output signal. However, the configuration of the Z-axis acceleration sensor element 36z is not particularly limited as long as the acceleration Az can be detected.

The configuration of the three-axis acceleration sensor 36 is not particularly limited. For example, the base 37a and the lid 37b may be formed of a material other than silicon such as glass. In the illustrated configuration, the acceleration sensor elements 36x, 36y, and 36z are arranged along the Y-axis directions, but the arrangement thereof is not particularly limited. The package 37 may be segmented for each of the acceleration sensor elements 36x, 36y, and 36z. In this case, the acceleration sensor elements 36x, 36y, and 36z may be disposed to overlap one another in the Z-axis directions. Two or more acceleration sensor elements selected from the acceleration sensor elements 36x, 36y, and 36z may be integrally formed as one acceleration sensor element. In other words, two or more of the accelerations Ax, Ay, and Az may be detected by one acceleration sensor element. The acceleration sensor is not limited to the three-axis acceleration sensor 36, and the number of acceleration detection axes may be two or one.

The circuit element 38 is electrically coupled to the three-axis angular velocity sensor 34 and the three-axis acceleration sensor 36 via the substrate 31. The circuit element 38 includes, for example, an MCU (Micro Controller Unit). As illustrated in FIG. 5, the circuit element 38 includes, for example, a control circuit unit 38a that controls driving of the three-axis angular velocity sensor 34 and the three-axis acceleration sensor 36, and an interface circuit unit 38b that communicates with the integrated circuit 60.

The control circuit unit 38a controls driving of the three-axis angular velocity sensor 34, detects the angular velocity ωx based on the output signal of the X-axis angular velocity sensor element 34x, detects the angular velocity ωy based on the output signal of the Y-axis angular velocity sensor element 34y, and detects the angular velocity ωz based on the output signal of the Z-axis angular velocity sensor element 34z. Further, the control circuit unit 38a controls driving of the three-axis acceleration sensor 36, detects the acceleration Ax based on the output signal of the X-axis acceleration sensor element 36x, detects the acceleration Ay based on the output signal of the Y-axis acceleration sensor element 36y, and detects the acceleration Az based on the output signal of the Z-axis acceleration sensor element 36z.

The interface circuit unit 38b transmits and receives a signal, receives a command from the integrated circuit 60, and outputs the detected angular velocities ωx, ωy, and ωz and accelerations Ax, Ay, and Az to the integrated circuit 60. Examples of a communication method between the interface circuit unit 38b and the integrated circuit 60 include SPI (Serial Peripheral Interface) communication. The SPI communication is a communication method suitable for connecting a plurality of sensors, and all signals related to the angular velocities ωx, ωy, and ωz and the accelerations Ax, Ay, and Az can be output from a single pin. Therefore, the number of pins of the MEMS sensor 30 can be reduced.

### 1.3. Vibrator Element

As shown in FIGS. 2 and 3, the vibrator element 40 is disposed in the first space 102. In the illustrated example, the vibrator element 40 is disposed in the first portion 25a of the first recess 25. The vibrator element 40 is an angular velocity sensor element that detects an angular velocity ωz around the Z axis. The vibrator element 40 is a quartz crystal vibrator element.

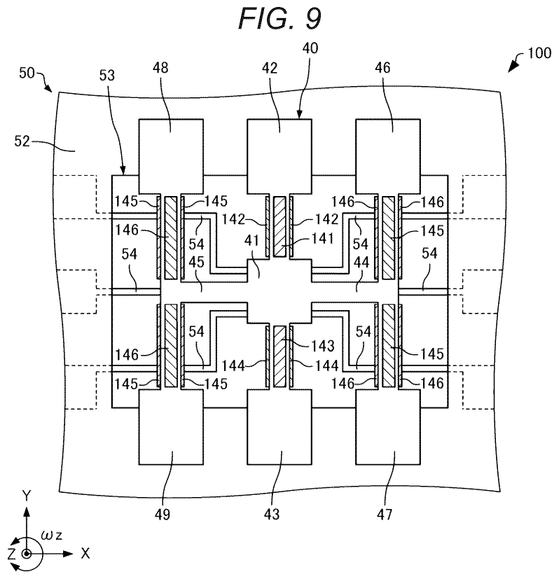

FIG. 9 is a plan view schematically illustrating the vibrator element 40. As illustrated in FIG. 9, the vibrator element 40 includes a base portion 41 located at the center, a pair of detection vibration arms 42 and 43 extending from the base portion 41 to both sides in the Y-axis directions, a pair of support arms 44 and 45 extending from the base portion 41 to both sides in the X-axis directions, a pair of drive vibration arms 46 and 47 extending from an end of one support arm 44 to both sides in the Y-axis directions, and a pair of drive vibration arms 48 and 49 extending from an end of the other support arm 45 to both sides in the Y-axis directions. The base portion 41, the detection vibration arms 42 and 43, the support arms 44 and 45, and the drive vibration arms 46, 47, 48, and 49 are integrally formed from a quartz crystal substrate. The vibrator element 40 is supported by the support substrate 50 at the base portion 41.

The vibrator element 40 further includes first detection signal electrodes 141 disposed on both principal surfaces of the detection vibration arm 42, first detection ground electrodes 142 disposed on both side surfaces of the detection vibration arm 42, second detection signal electrodes 143 disposed on both principal surfaces of the detection vibration arm 43, second detection ground electrodes 144 disposed on both side surfaces of the detection vibration arm 43, drive signal electrodes 145 disposed on both principal surfaces of the drive vibration arms 46 and 47 and both side surfaces of the drive vibration arms 48 and 49, and drive ground electrodes 146 disposed on both side surfaces of the drive vibration arms 46 and 47 and both principal surfaces of the drive vibration arms 48 and 49.

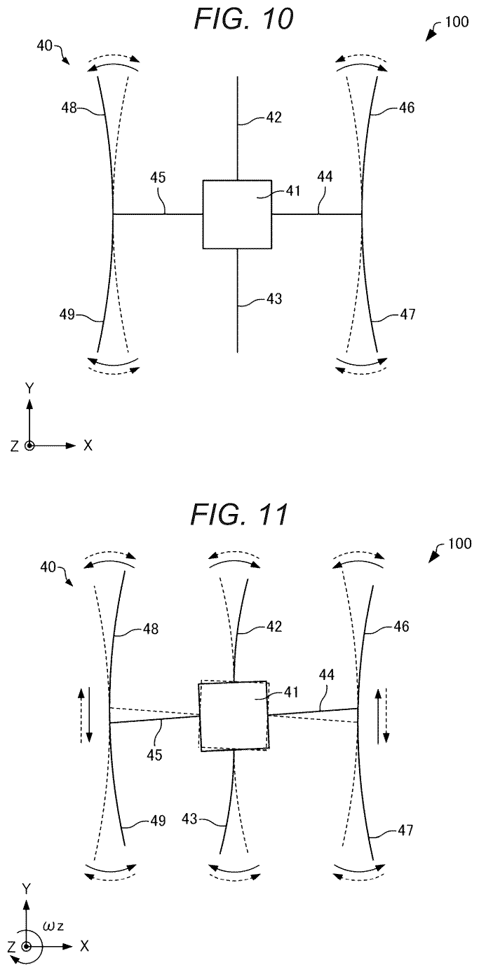

FIGS. 10 and 11 show the operation of the vibrator element 40. For convenience, the vibrator element 40 is illustrated in a simplified manner in FIGS. 10 and 11.

When a drive signal is applied to the drive signal electrodes 145, as shown in FIG. 10, the drive vibration arms 46 and 47 and the drive vibration arms 48 and 49 perform flexural vibrations in opposite phase in the X-axis directions (hereinafter, this state is also referred to as “drive vibration mode”). In the drive vibration mode, the vibration of the drive vibration arms 46 and 47 and the vibration of the drive vibration arms 48 and 49 are cancelled out, and the detection vibration arms 42 and 43 do not substantially vibrate.

When the angular velocity ωz is applied to the vibrator element 40 in the drive vibration mode, the Coriolis force acts on the drive vibration arms 46, 47, 48, and 49 to excite the flexural vibration in the Y-axis directions as shown in FIG. 11. Then, the detection vibration arms 42 and 43 flexurally vibrate in the X-axis directions in response to the flexural vibration (hereinafter, this state is also referred to as “detection vibration mode”).

The electric charge generated in the detection vibration arm 42 in the detection vibration mode is extracted as a first detection signal from the first detection signal electrodes 141, the electric charge generated in the detection vibration arm 43 is extracted as a second detection signal from the second detection signal electrodes 143, and the angular velocity ωz is obtained based on an output signal as a differential signal of the first detection signal and the second detection signal. A quartz crystal vibrator has better frequency-temperature characteristics than an element formed of silicon MEMS. Therefore, the vibrator element 40 as a quartz crystal vibrator can detect the angular velocity ωz with higher accuracy than the Z-axis angular velocity sensor element 34z formed of silicon MEMS.

When a bias error (output error during rest) of the output signal of the vibrator element 40 is Bz1 [deg/sec] and a bias error (output error during rest) of the output signal of the Z-axis angular velocity sensor element 34z is Bz2 [deg/sec], a relationship of Bz1 <Bz2 may be satisfied. Further, a relationship of Bz1 <0.7 Bz2 is preferably satisfied, a relationship of Bz1 <0.5 Bz2 is more preferably satisfied, and a relationship of Bz1 <0.3 Bz2 is even more preferably satisfied. The relationships described above are satisfied, and thus the vibrator element 40 can detect the angular velocity ωz with higher accuracy than the Z-axis angular velocity sensor element 34z.

The vibrator element 40 is exposed to the first space 102. That is, the vibrator element 40 is exposed and disposed in the first space 102. Therefore, for example, as compared with a case where the vibrator element is housed in a package and disposed in the first space, the size of the vibrator element 40 can be increased. Accordingly, a larger output signal is obtained, and the S/N is improved. Therefore, the detection accuracy of the angular velocity ωz can be further increased. Since the size is larger, the dimensional error is reduced, and the occurrence of spurious in the drive vibration state can be effectively suppressed. Accordingly, the bias error of the output signal of the vibrator element 40 can be further reduced. Therefore, the vibrator element 40 can detect the angular velocity ωz with higher accuracy.

The placement and the configuration of the vibrator element 40 are not particularly limited. For example, a silicon MEMS-type angular velocity sensor element may be used as the vibrator element 40.

### 1.4. Support Substrate

The support substrate 50 supports the vibrator element 40. Further, the support substrate 50 electrically couples the vibrator element 40 and the integrated circuit 60. As shown in FIGS. 2 and 3, the support substrate 50 is disposed in the first space 102. In the illustrated example, the support substrate 50 is disposed in the first portion 25a of the first recess 25 forming the first space 102.

The support substrate 50 is fixed to the base 22 of the package 20. The support substrate 50 is located below the vibrator element 40 and supports the vibrator element 40 so as to lift the vibrator element 40 from below. Since the support substrate 50 is provided between the base 22 and the vibrator element 40, stress is less likely to be applied to the vibrator element 40, and the detection accuracy of the angular velocity of the vibrator element 40 can be improved. For convenience, in FIG. 1, the support substrate 50 is illustrated in a simplified manner.

The support substrate 50 is, for example, a substrate for TAB (Tape Automated Bonding) mounting. As shown in FIG. 9, the support substrate 50 includes, for example, a substrate 52 and leads 54 coupled to the substrate 52. In the example shown in FIG. 3, the substrate 52 is provided over the step portion of the base 22. The step portion is a step formed by the first portion 25a and the second portion 25b of the first recess 25 having different sizes. As shown in FIG. 9, an opening 53 is formed in the substrate 52. The opening 53 penetrates the substrate 52 in the Z-axis directions. In plan view, the base portion 41 of the vibrator element 40 overlaps the opening portion 53.

The leads 54 are bonding leads that support the vibrator element 40. The lead 54 is a conductive wiring pattern. In the illustrated example, six of the leads 54 are provided. The leads 54 extend from the substrate 52 to the center of the opening 53 and support the base portion 41 of the vibrator element 40 at the center of the opening 53. Each of the six leads 54 is electrically coupled to the integrated circuit 60. The six leads 54 are respectively electrically coupled to the electrodes 141, 142, 143, 144, 145, and 146 of the vibrator element 40.

Note that the configuration of the support substrate 50 is not particularly limited. For example, the support substrate 50 may be formed by etching a quartz crystal planar plate to form a frame portion and beam portions extending from the frame portion toward the center of the planar plate, and providing wiring patterns on the frame portion and the beam portions.

### 1.5. Integrated Circuit

As shown in FIGS. 2 and 3, the integrated circuit 60 is disposed in the first space 102. In the illustrated example, the integrated circuit 60 is disposed in the second portion 25b of the first recess 25. The integrated circuit 60 is disposed on the flat plate portion 23 of the package 20 in the first space 102.

The integrated circuit 60 overlaps the vibrator element 40 and the MEMS sensor 30 in plan view. The vibrator element 40 overlaps the MEMS sensor 30 and the integrated circuit 60 in plan view. The MEMS sensor 30 overlaps the vibrator element 40 and the integrated circuit 60 in plan view. That is, the vibrator element 40, the integrated circuit 60, and the MEMS sensor 30 overlap one another in plan view. The integrated circuit 60 includes an MCU. The integrated circuit 60 is electrically coupled to the vibrator element 40 and the MEMS sensor 30.

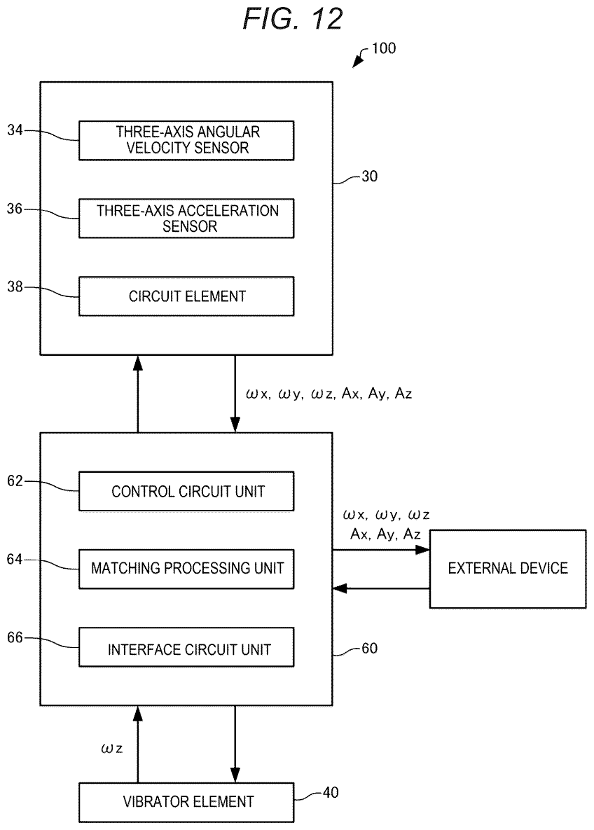

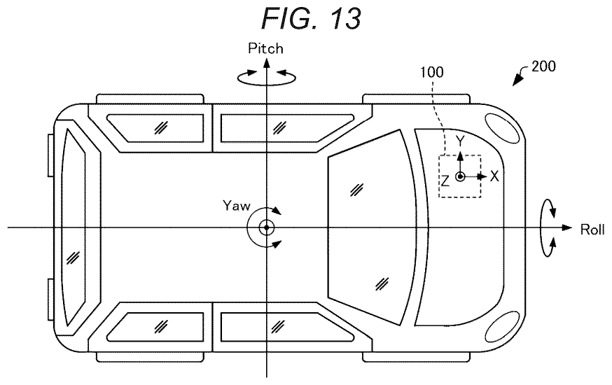

FIG. 12 is a block diagram showing the integrated circuit 60. As illustrated in FIG. 12, the integrated circuit 60 includes, for example, a control circuit unit 62 that controls driving of the vibrator element 40, a matching processing unit 64 that corrects an angle error in detection axis between the Z-axis angular velocity sensor element 34z and the vibrator element 40, and an interface circuit unit 66 that communicates with an external device.

The control circuit unit 62 controls driving of the vibrator element 40 and detects the angular velocity ωz based on the output signal of the vibrator element 40.

The matching processing unit 64 corrects the output signal of the vibrator element 40 based on the angle error of the detection axis of the vibrator element 40 with respect to the detection axis of the Z-axis angular velocity sensor element 34z. That is, alignment correction is performed on the output signal of the vibrator element 40 so that the detection axis of the vibrator element 40 is aligned with the detection axis of the Z-axis angular velocity sensor element 34z. Thus, an angular velocity around an axis aligned with the detection axis of the Z-axis angular velocity sensor element 34z can be detected by the vibrator element 40.

The interface circuit unit 66 transmits and receives a signal, receives a command from an external device, and outputs the angular velocities ωx, ωy, and ωz and the accelerations Ax, Ay, and Az detected by the MEMS sensor 30 and the angular velocity ωz detected by the vibrator element 40 to the external device. Examples of a communication method between the interface circuit unit 66 and the external device, the MEMS sensor 30, and the vibrator element 40 include SPI communication.

In the sensor module 100, as described above, the vibrator element 40 has higher detection accuracy of the angular velocity ωz than the Z-axis angular velocity sensor element 34z. Therefore, the interface circuit unit 66 may not output the angular velocity ωz detected by the Z-axis angular velocity sensor element 34z to the external device, but may collectively output a total of six signals of the angular velocities ωx and ωy and the accelerations Ax, Ay, and Az detected by the MEMS sensor 30 and the angular velocity ωz detected by the vibrator element 40 to the external device.

Alternatively, the interface circuit unit 66 may collectively output a total of seven signals of the angular velocities ωx, ωy, and ωz and the accelerations Ax, Ay, and Az detected by the MEMS sensor 30 and the angular velocity ωz detected by the vibrator element 40 to the external device. In this case, a user determines whether to use the angular velocity ωz detected by the Z-axis angular velocity sensor element 34z, to use the angular velocity ωz detected by the vibrator element 40, or to use both the angular velocities ωz.

Further, since the sensor module 100 has two sensors of the vibrator element 40 and the Z-axis angular velocity sensor element 34z as sensors that detect the angular velocity around the Z axis, even when one of the two sensors that detect the angular velocity around the Z axis fails, the angular velocity around the Z axis can be detected by the other. Therefore, robustness of angular velocity detection around the Z axis can be enhanced.

### 1.6. Functions and Effects

The sensor module 100 includes the package 20 having the first space 102 and the second space 104 overlapping when viewed from the first direction, the vibrator element 40 and the integrated circuit 60 disposed in the first space 102, and the MEMS sensor 30 disposed in the second space 104, the integrated circuit 60 is electrically coupled to the vibrator element 40 and the MEMS sensor 30, and the vibrator element 40, the integrated circuit 60, and the MEMS sensor 30 overlap when viewed from the first direction. Therefore, in the sensor module 100, for example, as compared with a case where the vibrator element, the integrated circuit, and the MEMS sensor do not overlap when viewed from the first direction, the occupied area can be reduced. Therefore, downsizing can be achieved.

In the sensor module 100, the package 20 includes the first recess 25 and the lid 28 that closes the first recess 25, and the first recess 25 forms the first space 102. Therefore, in the sensor module 100, the first space 102 can be hermetically sealed by the lid 28.

In the sensor module 100, the first recess 25 has the first portion 25a and the second portion 25b overlapping each other when viewed from the first direction, the first portion 25a is located between the lid 28 and the second portion 25b and has the area larger than that of the second portion 25b when viewed from the first direction, the vibrator element 40 is disposed in the first portion 25a, and the integrated circuit 60 is disposed in the second portion 25b. Therefore, in the sensor module 100, the vibrator element 40 and the integrated circuit 60 can be disposed to overlap each other in the first space 102 when viewed from the first direction.

In the sensor module 100, the package 20 includes the second recess 27 that opens to the side opposite to the first recess 25 and the flat plate portion 23 that defines the bottom surfaces of the first recess 25 and the second recess 27, and the second recess 27 forms the second space 104. Therefore, in the sensor module 100, the vibrator element 40, the integrated circuit 60, and the MEMS sensor 30 can be disposed to overlap one another when viewed from the first direction.

The sensor module 100 includes the substrate 10 that closes the second recess 27, and the MEMS sensor 30 is disposed on the substrate 10 in the second space 104. Therefore, in the sensor module 100, for example, as compared with a case where the MEMS sensor 30 is disposed on the flat plate portion 23, routing of wiring for electrically coupling the MEMS sensor 30 and the integrated circuit 60 can be simplified.

In the sensor module 100, the substrate 10 is softer than the package 20. Therefore, in the sensor module 100, when the sensor module 100 is mounted on a mounting substrate (not shown), stress applied to the vibrator element 40 and the MEMS sensor 30 due to the mounting on the mounting substrate can be relaxed by the substrate 10. Accordingly, characteristic fluctuations of the vibrator element 40 and the MEMS sensor 30 due to stress can be reduced.

In the sensor module 100, the substrate 10 has the second terminal 16 on the side opposite to the MEMS sensor 30. Therefore, in the sensor module 100, when the substrate 10 is mounted toward the mounting substrate, the mounting substrate and the second terminal 16 can be coupled to each other.

### 2. Vehicle

Next, a vehicle according to an embodiment will be described with reference to the drawing. FIG. 13 is a plan view schematically illustrating a vehicle 200 according to the present embodiment.

As illustrated in FIG. 13, the vehicle 200 is, for example, an automobile. The vehicle 200 is not limited to an automobile and may be, for example, a farm machine such as a tractor or a construction machine such as an excavator.

The vehicle 200 includes, for example, the sensor module 100. In the vehicle 200, the sensor module 100 is in an attitude in which the X axis is oriented in the front-rear direction of the vehicle 200, the Y axis is oriented in the left-right direction of the vehicle 200, and the Z axis is oriented in the up-down direction of the vehicle 200. Therefore, the X axis of the sensor module 100 is aligned with a roll axis of the vehicle 200. The Y axis of the sensor module 100 is aligned with a pitch axis of the vehicle 200. The Z axis of the sensor module 100 is aligned with a yaw axis of the vehicle 200. Therefore, the attitude of the vehicle 200 is expressed by a roll angle around the X axis, a pitch angle around the Y axis, and a yaw angle around the Z axis.

The roll angle corresponds to the inclination of the vehicle 200 in the left-right direction. The pitch angle corresponds to the inclination of the vehicle 200 in the front-rear direction. The yaw angle corresponds to a change in traveling direction or the azimuth direction of the vehicle 200.

In various kinds of control of the vehicle 200, the yaw angle corresponding to a change in traveling direction or the azimuth direction of the vehicle 200 is the most important of the roll angle, the pitch angle, and the yaw angle. This is because, while the detection error of the yaw angle (the difference between the actual value and the measured value) is directly linked to the traveling direction error of the vehicle 200 (the difference between the actual traveling direction and the measured traveling direction), the errors of the roll angle and the pitch angle are not directly linked to the traveling direction error of the vehicle 200. In order to reduce the traveling direction error of the vehicle 200, the detection accuracy of the yaw angle can be effectively further increased. A sensor that can detect all of the roll angle, the pitch angle, and the yaw angle with high accuracy may be used, but this causes an increase in size and cost of the sensor.

In the sensor module 100, the yaw angle can be detected with particularly high accuracy by the vibrator element 40, and the roll angle and the pitch angle can also be detected with sufficient accuracy by the MEMS sensor 30. Therefore, according to the sensor module 100, it is possible to effectively contribute to the reduction of the traveling direction error of the vehicle 200 while achieving a reduction in size and cost of the device. Therefore, the sensor module 100 has extremely good compatibility and high affinity with the vehicle 200.

The embodiments and the modifications described above are examples and the present disclosure is not limited thereto. For example, the embodiments and the modifications can also be combined as appropriate.

The present disclosure includes substantially the same configurations as configurations described in the embodiments, for example, configurations having the same functions, methods, and results or configurations having the same objects and effects. The present disclosure includes a configuration in which a non-essential portion of the configuration described in the embodiments is replaced. The present disclosure includes configurations that achieve the same functions and effects or configurations that can achieve the same objects as the configurations described in the embodiments. The present disclosure includes configurations obtained by adding publicly-known techniques to the configurations described in the embodiments.

The following configurations are derived from the embodiments and modifications described above.

An aspect of a sensor module includes a package having a first space and a second space overlapping when viewed from a first direction, a vibrator element and an integrated circuit disposed in the first space, and a MEMS sensor disposed in the second space, wherein the integrated circuit is electrically coupled to the vibrator element and the MEMS sensor, and the vibrator element, the integrated circuit, and the MEMS sensor overlap one another when viewed from the first direction.

According to the sensor module, the occupied area can be reduced.

In the aspect of the sensor module, the package may include a first recess and a lid that closes the first recess, and the first recess may form the first space.

According to the sensor module, the first space can be hermetically sealed by the lid.

In the aspect of the sensor module, the first recess may include a first portion and a second portion overlapping each other when viewed from the first direction, the first portion may be located between the lid and the second portion, may have an area when viewed from the first direction larger than that of the second portion, the vibrator element may be disposed in the first portion, and the integrated circuit may be disposed in the second portion.

According to the sensor module, the vibrator element and the integrated circuit can be disposed to overlap each other when viewed from the first direction in the first space.

In the aspect of the sensor module, the package may include a second recess that opens to a side opposite to the first recess, and a flat plate portion that defines bottom surfaces of the first recess and the second recess, and the second recess may form the second space.

According to the sensor module, the vibrator element, the integrated circuit, and the MEMS sensor can be disposed to overlap one another when viewed from the first direction.

In the aspect of the sensor module, the sensor module may further include a substrate that closes the second recess, and the MEMS sensor may be disposed on the substrate in the second space.

According to the sensor module, the routing of the wiring for electrically coupling the MEMS sensor and the integrated circuit can be simplified.

In the aspect of the sensor module, the substrate may be softer than the package.

According to the sensor module, characteristic fluctuations of the vibrator element and the MEMS sensor due to stress can be reduced.

In the aspect of the sensor module, the substrate may include a terminal on a side opposite to the MEMS sensor.

According to the sensor module, when the substrate is mounted toward a mounting substrate, the mounting substrate and the terminal can be coupled to each other.

An aspect of a vehicle includes the aspect of the sensor module.

What is claimed is:

1. A sensor module comprising:
a package having a first space and a second space overlapping when viewed from a first direction;
a vibrator element and an integrated circuit disposed in the first space; and
a MEMS sensor disposed in the second space, wherein the integrated circuit is electrically coupled to the vibrator element and the MEMS sensor, and
the vibrator element, the integrated circuit, and the MEMS sensor overlap one another when viewed from the first direction.

2. The sensor module according to claim 1, wherein
the package includes a first recess and a lid that closes the first recess, and
the first recess forms the first space.

3. The sensor module according to claim 2, wherein
the first recess has a first portion and a second portion overlapping each other when viewed from the first direction,
the first portion is located between the lid and the second portion, and has an area when viewed from the first direction larger than that of the second portion,
the vibrator element is disposed in the first portion, and
the integrated circuit is disposed in the second portion.

4. The sensor module according to claim 2, wherein
the package includes:
a second recess that opens to a side opposite to the first recess; and
a flat plate portion that defines bottom surfaces of the first recess and the second recess, and
the second recess forms the second space.

5. The sensor module according to claim 4, further comprising a substrate that closes the second recess, wherein
the MEMS sensor is disposed on the substrate in the second space.

6. The sensor module according to claim 5, wherein
the substrate is formed using a material softer than that of the package.

7. The sensor module according to claim 5, wherein
the substrate has a terminal on a side opposite to the MEMS sensor.

8. A vehicle comprising the sensor module according to claim 1.
